(19) United States
(12) Patent Application Publication
(10) Pub. No.: US 2025/0234666 A1
(43) Pub. Date: Jul. 17, 2025

(54) IMAGE SENSOR

(71) Applicant: SAMSUNG ELECTRONICS CO., LTD., Suwon-si (KR)

(72) Inventors: Yongkun Jo, Suwon-si (KR); Minho Jang, Suwon-si (KR); Jonghyun Go, Suwon-si (KR); Changkyu Lee, Suwon-si (KR)

(73) Assignee: SAMSUNG ELECTRONICS CO., LTD., Suwon-si (KR)

(21) Appl. No.: 18/902,005

(22) Filed: Sep. 30, 2024

(30) Foreign Application Priority Data
Jan. 12, 2024 (KR) 10-2024-0005567

(51) Int. Cl. H01L 27/146

(52) U.S. Cl. CPC H10F 39/811; H10F 39/8057

(57) ABSTRACT

An image sensor includes a top layer including a first front bonding pad on a first substrate, a first front bonding plug connected to the first front bonding pad, and a first shield structure apart from the first front bonding pad in a first horizontal direction, a middle layer below the top layer and bonded to the top layer, the middle layer including a second front bonding pad on a second substrate, a second front bonding plug connected to the second front bonding pad, and a second shield structure apart from the second front bonding pad in the first horizontal direction, and a bottom layer below the middle layer and bonded to the middle layer, wherein a vertical level of a top surface of the first shield structure is higher than a vertical level of a top surface of the first front bonding pad.

### CROSS-REFERENCE TO RELATED APPLICATION

This application is based on and claims priority to Korean Patent Application No. 10-2024-0005567, filed on Jan. 12, 2024, in the Korean Intellectual Property Office, the disclosure of which is incorporated by reference herein in its entirety.

### BACKGROUND

### 1. Field

The disclosure relates to an image sensor, and more particularly, to an image sensor capable of improving coupling that occurs due to the miniaturization of the image sensor.

### 2. Description of Related Art

Image sensors that capture images and convert images into electrical signals are used in electronic devices for general consumers such as digital cameras, mobile phone cameras, and portable camcorders, and also in cameras mounted on cars, security devices, and robots. As image sensors are becoming smaller, there is a need to improve coupling that occurs due to the miniaturization of the image sensors.

### SUMMARY

Provided is an image sensor capable of improving coupling that occurs due to the miniaturization of the image sensor.

Further provided is an image sensor having improved electrical characteristics and reliability.

Further provided is an image sensor having an increased integration density.

The disclosure is not limited to what is mentioned above and will be clearly understood by those skilled in the art from the descriptions below.

According to an aspect of the disclosure, an image sensor includes: a top layer including a first substrate, the first substrate including: a first front surface and a first back surface opposite to the first front surface; a first front bonding pad on the first front surface; a first front bonding plug connected to the first front bonding pad and extending in a vertical direction toward the first front surface; and a first shield structure separate from the first front bonding pad in a first horizontal direction; a middle layer below the top layer and bonded to the top layer, the middle layer including: a second substrate including a second front surface and a second back surface opposite to the second front surface; a second front bonding pad on the second front surface; a second front bonding plug connected to the second front bonding pad and extending in the vertical direction toward the second front surface; and a second shield structure separated from the second front bonding pad in the first horizontal direction; and a bottom layer below the middle layer and bonded to the middle layer, the bottom layer including a third substrate and a transistor on the third substrate, wherein a vertical level of a top surface of the first shield structure is higher than a vertical level of a top surface of the first front bonding pad.

According to an aspect of the disclosure, an image sensor includes: a top layer including a first substrate, the first substrate including: a first front surface and a first back surface opposite to the first front surface; a first front bonding pad on the first front surface; a first front bonding plug connected to the first front bonding pad and extending in a vertical direction toward the first front surface; and a first shield structure including a first portion separate from the first front bonding pad in a first horizontal direction and a second portion separate from the first front bonding plug in the first horizontal direction; a middle layer below the top layer and bonded to the top layer, the middle layer including: a second substrate including a second front surface and a second back surface opposite to the second front surface; a second front bonding pad on the second front surface; a second front bonding plug connected to the second front bonding pad and extending in the vertical direction toward the second front surface; and a second shield structure including a third portion separate from the second front bonding pad in the first horizontal direction and a fourth portion separate from the second front bonding plug in the first horizontal direction; and a bottom layer below the middle layer and bonded to the middle layer, the bottom layer including a third substrate and a transistor on the third substrate, wherein the first shield structure and the second shield structure extend in a second horizontal direction that intersects with the first horizontal direction.

According to an aspect of the disclosure, an image sensor includes: a top layer including a first substrate, the first substrate including: a first front surface and a first back surface opposite to the first front surface; a color filter and a lens sequentially stacked on the first back surface; a pixel isolation layer penetrating the first substrate; a first transistor on the first front surface of the first substrate; a first contact plug connected to the first transistor; a first wiring layer below the first contact plug and connected to the first contact plug; a first front bonding plug below the first wiring layer and connected to the first wiring layer; a first front bonding pad below the first front bonding plug and in contact with the first front bonding plug; and a first shield structure separate from the first front bonding pad in a first horizontal direction; a middle layer below the top layer and bonded to the top layer, the middle layer including a second substrate, the second substrate including: a second front surface and a second back surface opposite to the second front surface; a second transistor on the second front surface; a second contact plug connected to the second transistor; a second wiring layer above the second contact plug and connected to the second contact plug; a second front bonding plug above the second wiring layer and connected to the second wiring layer; a second front bonding pad above the second front bonding plug and in contact with the second front bonding plug; and a second shield structure separate from the second front bonding pad in the first horizontal direction; and a bottom layer below the middle layer and bonded to the middle layer, the bottom layer including a third substrate and a transistor on the third substrate, wherein a vertical level of a top surface of the first shield structure is higher than a vertical level of a top surface of the first front bonding pad.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram of an image sensor according to an embodiment;

FIG. 2 is a circuit diagram of an image sensor according to an embodiment;

FIG. 3 is a schematic cross-sectional view illustrating the structure of an image sensor according to an embodiment;

FIG. 4 is an enlarged view of a region PP1 in FIG. 3;

FIG. 5 is a schematic plan view illustrating the structure of an image sensor according to an embodiment;

FIG. 6 is a schematic plan view illustrating the structure of an image sensor according to an embodiment;

FIG. 7 is a schematic cross-sectional view illustrating the structure of an image sensor according to an embodiment;

FIG. 8 is an enlarged view of a region PP2 in FIG. 7; and

FIGS. 9, 10, 11, 12, 13, 14 and 15 are cross-sectional views illustrating a method of manufacturing the image sensor of FIG. 3, according to an embodiment.

### DETAILED DESCRIPTION

Hereinafter, embodiments are described in detail with reference to the accompanying drawings. Embodiments may have only one implementation or may be implemented in combination with one or more embodiments. Accordingly, the disclosure is not limited to one embodiment.

As used herein, the singular forms “a”, “an”, and “the” are intended to include the plural forms as well, unless the context clearly indicates otherwise. The drawings may be exaggerated for clarity and are not drawn to scale. While terms including ordinal numbers such as “first,” “second,” etc., may be used for convenience of description, the disclosure is not limited to the above terms.

In the following description, like reference numerals refer to like elements throughout the specification. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

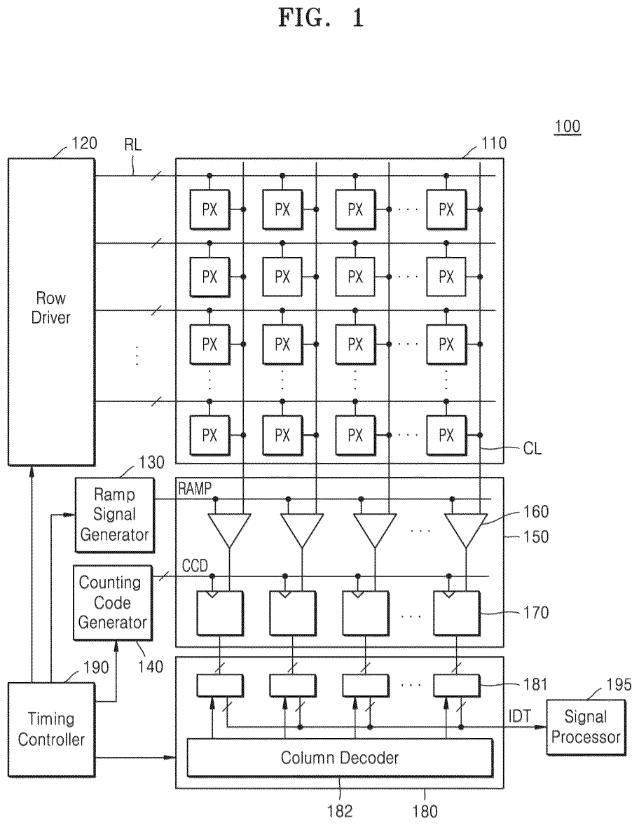

FIG. 1 is a block diagram of an image sensor 100 according to an embodiment.

The image sensor 100 may include a pixel array 110, a row driver 120, a ramp signal generator 130, a counting code generator 140, an analog-to-digital converter (ADC) circuit 150, a data output circuit 180, and a timing controller 190. The image sensor 100 may further include a signal processor 195. A configuration including the ADC circuit 150 and the data output circuit 180 may be referred to as a readout circuit.

The pixel array 110 may include a plurality of row lines RL and a plurality of column lines CL. The pixel array 110 may include a plurality of pixels PX, which are connected to the row lines RL and the column lines CL and arranged in a matrix. The pixels PX may include an active pixel sensor (APS).

Each of the pixels PX may include at least one photoelectric conversion element, may sense light by using the photoelectric conversion element, and may generate an image signal that is an electrical signal converted from the sensed light. For example, the photoelectric conversion element may include a photodiode, a phototransistor, a photogate, a pinned photodiode, or the like.

Each of the pixels PX may sense light in a particular spectrum. For example, some of the pixels PX may convert light in a red spectrum into an electrical signal, convert light in a green spectrum into an electrical signal, or convert light in a blue spectrum into an electrical signal. However, the disclosure is not limited thereto. At least some of the pixels PX may convert light in a white spectrum into an electrical signal.

For example, at least some of the pixels PX may convert light in a different color spectrum than the red, green, blue, and white spectra into an electrical signal. For example, at least some of the pixels PX may convert light in a yellow, cyan, or magenta spectrum into an electrical signal.

A color filter transmitting light in a particular spectrum may be arranged above each of the pixels PX. A color sensed by each pixel PX may be determined by a color filter. However, the disclosure is not limited thereto. In one or more embodiments, a particular photoelectric conversion element may convert light in a particular wavelength band into an electrical signal according to the level of an electrical signal applied thereto.

In one or more embodiments, each of the pixels PX may have dual conversion gain. Dual conversion gain includes a low conversion gain and a high conversion gain. Here, a conversion gain is a ratio at which charge accumulated in a floating diffusion node is converted into voltage. Charge generated by a photoelectric conversion element may be transferred to and accumulated in a floating diffusion node, and the charge in the floating diffusion node may be converted into voltage according to conversion gain. The conversion gain may vary with the capacitance of the floating diffusion node. The conversion gain may decrease when the capacitance of the floating diffusion node increases and increase when the capacitance of the floating diffusion node decreases.

The row driver 120 may drive the pixel array 110 row-by-row. The row driver 120 may decode a row control signal (e.g., an address signal) generated by the timing controller 190. The row driver 120 may select at least one of the row lines RL of the pixel array 110 in response to a decoded row control signal.

For example, the row driver 120 may generate a selection signal for selecting one of a plurality of rows. The selection signal may be transmitted to the pixel array 110 through the row line RL. The pixel array 110 may output a pixel signal (e.g., a pixel voltage) from a row, which is selected by the selection signal from the row driver 120. The pixel signal may include a reset signal and an image signal. The row driver 120 may transmit control signals to the pixel array 110. Control signals may be signals for outputting pixel signals. Each of the pixels PX may output a pixel signal by operating in response to the control signals.

The ramp signal generator 130 may generate a ramp signal RAMP (e.g., a ramp voltage), which increases or decreases with a certain slope under control of the timing controller 190. The ramp signal RAMP may be provided to each of a plurality of correlated double sampling (CDS) circuits 160 of the ADC circuit 150.

The counting code generator 140 may generate a counting code CCD under control of the timing controller 190. The counting code CCD may be provided to a plurality of counter circuits 170. In one or more embodiments, the counting code generator 140 may include a gray code generator. The counting code generator 140 may generate, as the counting code CCD, a plurality of code values having a resolution corresponding to a set number of bits. For example, when a 10-bit code is set, the counting code generator 140 may generate the counting code CCD including 1,024 code values in ascending or descending order.

The ADC circuit 150 may include the CDS circuits 160 and the counter circuits 170. The ADC circuit 150 may convert a pixel signal received from the pixel array 110 into a pixel value corresponding to a digital signal. A pixel signal received through each of the column lines CL may be converted by a CDS circuit 160 and a counter circuit 170 into a pixel value corresponding to a digital signal.

The CDS circuit 160 may compare a pixel signal, which is received through a column line CL, with the ramp signal RAMP and output a result of the comparison as a comparison signal. The CDS circuit 160 may output a comparison signal, which transits from a first level (e.g., logic high) to a second level (e.g., logic low), when the level of the ramp signal RAMP is equal to the level of a pixel signal. A level transition time of the comparison signal may be determined according to the level of the pixel signal.

The CDS circuit 160 may sample a pixel signal provided from a pixel PX by using a CDS method. The CDS circuit 160 may sample a reset signal received as a pixel signal, compare the reset signal with the ramp signal RAMP, and generate a comparison signal according to the reset signal. Thereafter, the CDS circuit 160 may sample an image signal correlated with the reset signal, compare the image signal with the ramp signal RAMP, and generate a comparison signal according to the image signal.

The counter circuit 170 may count the level transition time of a comparison signal output from the CDS circuit 160 and output a count value. In one or more embodiments, the counter circuit 170 may include a latch circuit and an operational circuit. The latch circuit may receive the counting code CCD from the counting code generator 140 and the comparison signal from the CDS circuit 160 and latch a code value of the counting code CCD at the level transition time of the comparison signal.

The latch circuit may latch a code value corresponding to a reset signal. For example, the latch circuit may latch a reset value and a code value corresponding to an image signal. For example, the latch circuit may latch an image signal value. The operational circuit may perform an operation on the reset value and the image signal value, thereby generating an image signal value having a reset level of the pixel PX removed therefrom. The counter circuit 170 may output, as a pixel value, the image signal value having the reset level removed therefrom.

In an embodiment, the image sensor 100 may include the counting code generator 140 and the counter circuit 170, and the counter circuit 170 may include a circuit latching a code value of the counting code CCD received from the counting code generator 140, but the disclosure is not limited thereto.

In one or more embodiments, the image sensor 100 may not include the counting code generator 140, and the counter circuit 170 may include an up counter, which sequentially increases a count value based on a counting clock signal provided from the timing controller 190, and an operational circuit, or may include an up-down counter or a bitwise inversion counter.

The data output circuit 180 may temporarily store a pixel value output from the ADC circuit 150 and then output the pixel value. The data output circuit 180 may include a plurality of column memories 181 and a column decoder 182. Each of the column memories 181 may store a pixel value received from the counter circuit 170. In one or more embodiments, each column memory 181 may be included in the counter circuit 170. A plurality of pixel values respectively stored in the column memories 181 may be output as image data IDT under control of the column decoder 182.

The timing controller 190 may output a control signal to each of the row driver 120, the ramp signal generator 130, the counting code generator 140, the ADC circuit 150, and the data output circuit 180 and thus control the operations or timing of the row driver 120, the ramp signal generator 130, the counting code generator 140, the ADC circuit 150, and the data output circuit 180.

The signal processor 195 may perform noise reduction, gain tuning, waveform shaping, interpolation, white balance, a gamma process, edge enhancement, binning, or the like on the image data IDT. In one or more embodiments, the signal processor 195 may be provided in a processor outside the image sensor 100.

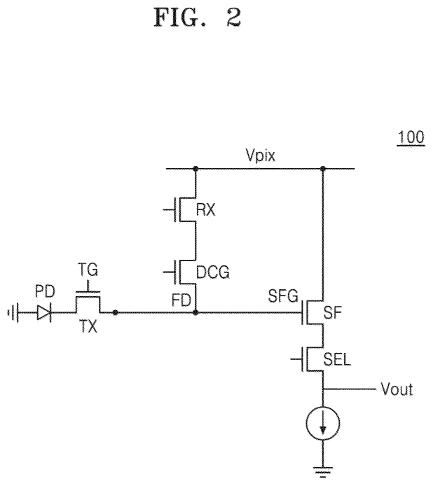

FIG. 2 is a circuit diagram of the image sensor 100 according to an embodiment.

Referring to FIG. 2, the image sensor 100 may include a photodiode PD, a transfer transistor TX, a floating diffusion node FD, a conversion gain transistor DCG, a reset transistor RX, a source follower transistor SF, and a select transistor SEL.

The transfer transistor TX, the conversion gain transistor DCG, the reset transistor RX, the source follower transistor SF, and the select transistor SEL may respectively include a transfer gate TG, a conversion gain gate, a reset gate, a source follower gate SFG, and a select gate.

In one or more embodiments, the transfer gate TG may include a vertical gate. In one or more embodiments, each of the conversion gain gate, the reset gate, the source follower gate SFG, and the select gate may include a flat gate.

The photodiode PD may generate charge in proportion to the amount of incident light. The photodiode PD may generate negatively charged electrons and positively charged holes in response to incident light.

There may be a plurality of photodiodes PD. The photodiodes PD may share the floating diffusion node FD, the reset transistor RX, the conversion gain transistor DCG, the source follower transistor SF, and the select transistor SEL. Providing one photodiode PD or eight photodiodes PD is just an example, and the number of photodiodes PD is not limited thereto. The transfer transistor TX may be between the photodiode PD and the floating diffusion node FD and may transfer charge generated in the photodiode PD to the floating diffusion node FD.

The transfer transistor TX may include the transfer gate TG, a drain connected to the photodiode PD, and a source connected to the floating diffusion node FD. The conversion gain transistor DCG may include the conversion gate, a source connected to a drain of the reset transistor RX, and a drain connected to the floating diffusion node FD.

The conversion gain transistor DCG may change the capacitance of the floating diffusion node FD according to a conversion gain signal.

When the conversion gain transistor DCG is turned on, the capacitance of the floating diffusion node FD may increase so that the image sensor 100 may operate in a low conversion gain mode. Contrarily, when the conversion gain transistor DCG is turned off, the capacitance of the floating diffusion node FD may decrease so that the image sensor 100 may operate in a high conversion gain mode. The reset transistor RX may include the reset gate, a source connected to a power supply voltage Vpix, and a drain connected to the source of the conversion gain transistor DCG.

When the reset transistor RX is turned on according to a reset control signal and the conversion gain transistor DCG is turned on according to the conversion gain signal, the floating diffusion node FD may be reset based on the power supply voltage Vpix. In detail, charge accumulated in the floating diffusion node FD may be discharged so that the floating diffusion node FD may be reset. At this time, a reset signal corresponding to the voltage level of the floating diffusion node FD may be output. The source follower gate SFG of the source follower transistor SF may be electrically connected to the floating diffusion node FD.

A source of the source follower transistor SF may be electrically connected to a source of the select transistor SEL. A drain of the source follower transistor SF may be electrically connected to the power supply voltage Vpix. The potential of the floating diffusion node FD may change according to the amount of charge accumulated in the floating diffusion node FD. The source follower transistor SF may amplify the potential change of the floating diffusion node FD and output an amplified result to the source of the source follower transistor SF.

The source of the select transistor SEL may be electrically connected to the select gate and the source of the source follower transistor SF.

A drain of the select transistor SEL may be electrically connected to an output voltage line Vout.

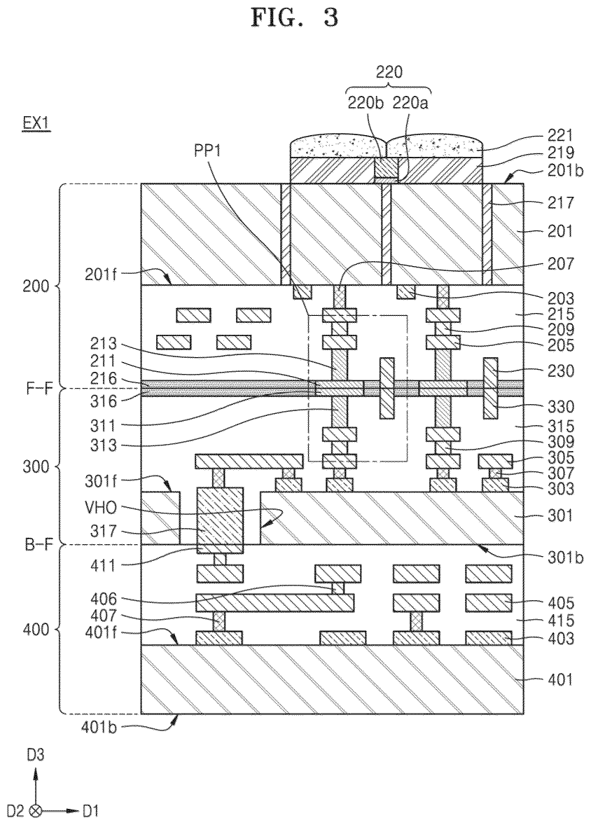

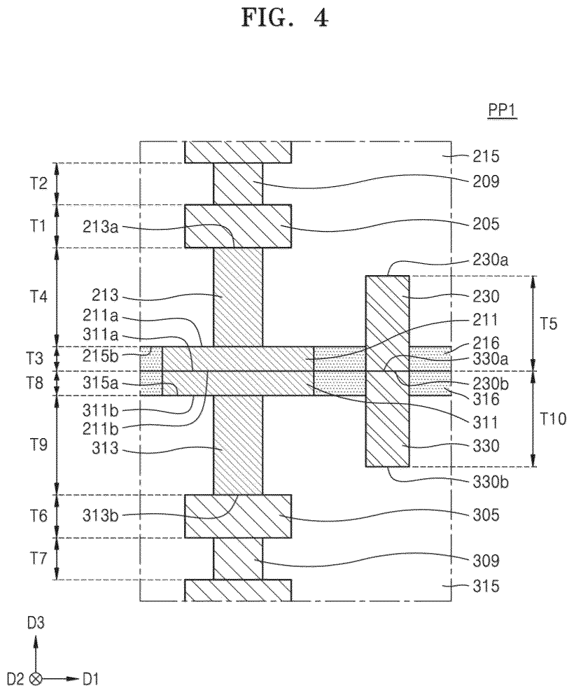

FIG. 3 is a schematic cross-sectional view illustrating the structure of an image sensor according to an embodiment. FIG. 4 is an enlarged view of a region PP1 in FIG. 3. Specifically, an image sensor EX1 of FIG. 3 may be an example implementation of the image sensor 100 of FIG. 1. Referring to FIGS. 3 and 4, the image sensor EX1 may include a pixel PX in FIG. 1.

The image sensor EX1 may include a top layer 200, a middle layer 300, and a bottom layer 400. The middle layer 300 and the top layer 200 may be sequentially stacked on the bottom layer 400.

The image sensor EX1 may be constituted of three layers in which the middle layer 300 and the top layer 200 are stacked on the bottom layer 400. The image sensor EX1 may be constituted of three layers in which the bottom layer 400, the middle layer 300, and the top layer 200 are bonded to each other. Hereinafter, a transistor may include a planar transistor, a multi-bridge channel (MBC) transistor, a gate-all-around (GAA) transistor, or a fin field-effect transistor (FET).

The top layer 200 may include a first substrate 201, a pixel isolation layer 217, a color filter 219, a lens 221, a plurality of first transistors 203, a first wiring layer 205, a first contact plug 207, a first via plug 209, a first front bonding pad 211, a first front bonding plug 213, a first shield structure 230, a first insulating layer 215, and a first passivation layer 216.

The first substrate 201 may include a silicon substrate.

The first substrate 201 may include a first front surface 201f and a first back surface 201b opposite to the first front surface 201f. Photodiodes (PD in FIG. 2) may be arranged in the first substrate 201. In one or more embodiments, one photodiode may be provided opposite to the color filter 219 and the lens 221. In one or more embodiments, a plurality of photodiodes may be provided in correspondence to the color filter 219 and the lens 221. The color filter 219 and the lens 221 may be arranged on the first back surface 201b of the first substrate 201.

The color filter 219 and the lens 221 may be sequentially stacked on the first back surface 201b of the first substrate 201. Although a plurality of lenses 221 are shown as being separated from each other in FIG. 3, the lenses 221 may be integrally formed. This may vary with the design of the image sensor EX1 to be manufactured. The pixel isolation layer 217 may be arranged inside the first substrate 201.

The pixel isolation layer 217 may isolate a plurality of pixels PX in FIG. 1 from each other. The pixel isolation layer 217 may penetrate the first substrate 201. The pixel isolation layer 217 may include at least two materials. For example, the pixel isolation layer 217 may include a semiconductor material and an insulating material having a refractive index different from that of the first substrate 201. For example, the semiconductor material may include an impurity-doped polysilicon film or an impurity-doped silicon germanium film. Impurities with which a polysilicon film or a silicon germanium film is doped may include, for example, boron, phosphorous, or arsenic. For example, the insulating material may include silicon oxide. The pixel isolation layer 217 may include a metal film instead of a semiconductor material. A fence pattern 220 may be arranged on the pixel isolation layer 217.

For example, the fence pattern 220 may vertically overlap the pixel isolation layer 217. However, this is just an example, and the fence pattern 220 may not vertically overlap the pixel isolation layer 217. The fence pattern 220 may be between a pair of color filters 219 adjacent to each other in a first horizontal direction D1.

The fence pattern 220 may separate a plurality of color filters 219 from each other. For example, the color filters 219 may be physically and optically separated from each other by the fence pattern 220. In a plan view, the fence pattern 220 may surround each of the pixels PX in FIG. 1.

For example, the fence pattern 220 may surround each of the color filters 219. The fence pattern 220 may include a first fence component 220a and a second fence component 220b on the first fence component 220a.

For example, the first fence component 220a and the second fence component 220b may have a rectangular cross-section. The first fence component 220a may function as a barrier layer.

The first fence component 220a may include a metal and/or a conductive material such as metal nitride. For example, the first fence component 220a may include titanium and/or titanium nitride. The second fence component 220b may include a different material than the first fence component 220a.

For example, the second fence component 220b may include an organic material. The second fence component 220b may include a material having a low-refractive index and may have an insulating characteristic. A first transistor 203 may be arranged on the first front surface 201f of the first substrate 201.

First source and drain regions of the first transistor 203 may be arranged in the first substrate 201 but are omitted from FIG. 3 for convenience. The first contact plug 207 and the first wiring layer 205 may be connected to the first transistor 203.

The first contact plug 207 may include a conductive metal. For example, the first contact plug 207 may include tungsten. There may be a plurality of first wiring layers 205. Two different first wiring layers 205 among the plurality of first wiring layers 205 may be at different vertical levels. In other words, the plurality of first wiring layers 205 may form a multi-layer structure. A first wiring layer 205 may be connected to the first via plug 209.

The first via plug 209 may connect at least two first wiring layers 205 at different vertical levels to each other. The first front bonding pad 211 may be at the bottom of the top layer 200.

The first front bonding pad 211 may be connected to the first front bonding plug 213. The first front bonding plug 213 may extend in a vertical direction D3 and be connected to the first wiring layer 205. Here, the first horizontal direction D1 is defined as a direction that is parallel with the first front surface 201f of the first substrate 201, a second horizontal direction D2 is defined as a direction that is parallel with the first front surface 201f of the first substrate 201 and crosses the first horizontal direction D1, and the vertical direction D3 is defined as a direction that is perpendicular to the first front surface 201f of the first substrate 201.

For example, the first front bonding pad 211 and the first front bonding plug 213 may be formed integrally.

In other words, the boundary between the first front bonding pad 211 and the first front bonding plug 213 may not be observed. The first front bonding pad 211 may be electrically connected to the first transistor 203 through the first front bonding plug 213, the first wiring layer 205, the first via plug 209, and the first contact plug 207.

For example, the first front bonding pad 211 may be electrically connected to the floating diffusion node FD in FIG. 2. The first wiring layer 205 may have a first thickness T1.

The first via plug 209 may have a second thickness T2. The first front bonding pad 211 may have a third thickness T3. The first front bonding plug 213 may have a fourth thickness T4. The first thickness T1 may correspond to the length of the first wiring layer 205 in the vertical direction D3.

The second thickness T2 may correspond to the length of the first via plug 209 in the vertical direction D3. The third thickness T3 may correspond to the length of the first front bonding pad 211 in the vertical direction D3. The fourth thickness T4 may correspond to the length of the first front bonding plug 213 in the vertical direction D3. The third thickness T3 of the first front bonding pad 211 may be less than the first thickness T1 of the first wiring layer 205.

The fourth thickness T4 of the first front bonding plug 213 may be greater than the second thickness T2 of the first via plug 209. The first shield structure 230 may be arranged beside the first front bonding pad 211.

The first shield structure 230 may be separate from the first front bonding pad 211 in the first horizontal direction D1. The first shield structure 230 may be between two first front bonding pads 211 adjacent to each other in the first horizontal direction D1. The first shield structure 230 may extend in the vertical direction D3 toward the first front surface 201f of the first substrate 201. The first shield structure 230 may be separate from the first front bonding pad 211, the first front bonding plug 213, the first wiring layer 205, and the first via plug 209. The first shield structure 230 may include a first portion, which is separate from the first front bonding pad 211 in the first horizontal direction D1, and a second portion, which is separate from the first front bonding plug 213 in the first horizontal direction D1.

The first portion of the first shield structure 230 may be arranged at the same vertical level as the first front bonding pad 211. The second portion of the first shield structure 230 may be arranged at the same vertical level as the first front bonding plug 213. The first portion and the second portion of the first shield structure 230 may be formed integrally. The first shield structure 230 may vertically overlap the pixel isolation layer 217.

In a plan view, the first shield structure 230 may overlap the pixel isolation layer 217. A bottom surface 230b of the first shield structure 230 may be coplanar with a bottom surface 211b of the first front bonding pad 211.

The vertical level of a top surface 230a of the first shield structure 230 may be higher than the vertical level of a top surface 211a of the first front bonding pad 211. The vertical level of the top surface 230a of the first shield structure 230 may be lower than the vertical level of a top surface 213a of the first front bonding plug 213. The first shield structure 230 may have a fifth thickness T5.

The fifth thickness T5 may correspond to the length of the first shield structure 230 in the vertical direction D3. The fifth thickness T5 of the first shield structure 230 may be greater than the third thickness T3 of the first front bonding pad 211. The fifth thickness T5 of the first shield structure 230 may be less than or equal to the sum of the third thickness T3 of the first front bonding pad 211 and the fourth thickness T4 of the first front bonding plug 213. For example, the fifth thickness T5 of the first shield structure 230 may be different from the fourth thickness T4 of the first front bonding plug 213. For example, the fifth thickness T5 of the first shield structure 230 may be less than or equal to the fourth thickness T4 of the first front bonding plug 213. For example, the fifth thickness T5 of the first shield structure 230 may be greater than the fourth thickness T4 of the first front bonding plug 213. In the cross-sectional view of FIG. 4, the width of the first shield structure 230 in the first horizontal direction D1 may be less than the width of the first front bonding pad 211 in the first horizontal direction D1.

The width of the first shield structure 230 in the first horizontal direction D1 may be less than or substantially equal to the width of the first front bonding plug 213 in the first horizontal direction D1. The first wiring layer 205, the first via plug 209, the first front bonding pad 211, the first front bonding plug 213, and the first shield structure 230 may include the same material.

The first wiring layer 205, the first via plug 209, the first front bonding pad 211, the first front bonding plug 213, and the first shield structure 230 may include conductive metal. For example, the first wiring layer 205, the first via plug 209, the first front bonding pad 211, the first front bonding plug 213, and the first shield structure 230 may include copper. The first insulating layer 215 may be arranged on the first front surface 201f of the first substrate 201.

The first wiring layer 205, the first contact plug 207, the first via plug 209, and the first front bonding plug 213 may be arranged inside the first insulating layer 215. The first insulating layer 215 may surround a portion of the first shield structure 230. The first shield structure 230 may further extend in the vertical direction D3 downwards from a bottom surface 215b of the first insulating layer 215. The first front bonding pad 211 may be disposed under the bottom surface 215b of the first insulating layer 215. The vertical level of the bottom surface 215b of the first insulating layer 215 may be higher than the vertical levels of the bottom surface 211b of the first front bonding pad 211 and the bottom surface 230b of the first shield structure 230.

The first insulating layer 215 may include silicon oxide. The first passivation layer 216 may be disposed on the bottom surface 215b of the first insulating layer 215.

The first passivation layer 216 may surround the side surface of the first front bonding pad 211. The bottom surface of the first passivation layer 216 may be coplanar with the bottom surface 211b of the first front bonding pad 211 and the bottom surface 230b of the first shield structure 230. The first passivation layer 216 may include silicon oxynitride. The middle layer 300 may include a second substrate 301, a plurality of second transistors 303, a back bonding through via 317, a second wiring layer 305, a second contact plug 307, a second via plug 309, a second front bonding pad 311, a second front bonding plug 313, a second shield structure 330, a second insulating layer 315, and a second passivation layer 316.

The first front bonding pad 211 of the top layer 200 may be bonded to the second front bonding pad 311 of the middle layer 300.

The first passivation layer 216 of the top layer 200 may be bonded to the second passivation layer 316 of the middle layer 300. The top layer 200 and the middle layer 300 may have an interface F-F at which a front surface F of the top layer 200 is bonded to a front surface F of the middle layer 300. The second substrate 301 may include a silicon substrate.

The second substrate 301 may include a second front surface 301f and a second back surface 301b opposite to the second front surface 301f. A second transistor 303 may be arranged on the second front surface 301f of second substrate 301. Second source and drain regions of the second transistor 303 may be arranged in the second substrate 301 but are omitted from FIG. 3 for convenience. A through via hole VHO may be arranged inside the second substrate 301 to penetrate the second substrate 301 from the second front surface 301f to the second back surface 301b of the second substrate 301.

The back bonding through via 317, which is insulated from the second substrate 301 by the second insulating layer 315, may be arranged in the through via hole VHO. The second contact plug 307 and the second wiring layer 305 may be connected to the second transistor 303.

The second contact plug 307 may include a conductive metal. For example, the second contact plug 307 may include tungsten. The second contact plug 307 and the second wiring layer 305 may be connected to the second front bonding pad 311 and the back bonding through via 317. There may be a plurality of second wiring layers 305.

Two different second wiring layers 305 among the plurality of second wiring layers 305 may be at different vertical levels. In other words, the plurality of second wiring layers 305 may form a multi-layer structure. A second wiring layer 305 may be connected to the second via plug 309.

The second via plug 309 may connect at least two second wiring layers 305 at different vertical levels to each other. The second front bonding pad 311 may be at the top of the middle layer 300.

The second front bonding pad 311 may be connected to the second front bonding plug 313. The second front bonding plug 313 may extend in the vertical direction D3 and be connected to the second wiring layer 305. For example, the second front bonding pad 311 and the second front bonding plug 313 may be formed integrally.

In other words, the boundary between the second front bonding pad 311 and the second front bonding plug 313 may not be observed. The second front bonding pad 311 may be electrically connected to the second transistor 303 through the second front bonding plug 313, the second wiring layer 305, the second via plug 309, and the second contact plug 307.

For example, the second front bonding pad 311 may be electrically connected to the gate of the source follower transistor SF in FIG. 2. The second wiring layer 305 may have a sixth thickness T6.

The second via plug 309 may have a seventh thickness T7. The second front bonding pad 311 may have an eighth thickness T8. The second front bonding plug 313 may have a ninth thickness T9. The sixth thickness T6 may correspond to the length of the second wiring layer 305 in the vertical direction D3.

The seventh thickness T7 may correspond to the length of the second via plug 309 in the vertical direction D3. The eighth thickness T8 may correspond to the length of the second front bonding pad 311 in the vertical direction D3. The ninth thickness T9 may correspond to the length of the second front bonding plug 313 in the vertical direction D3. The eighth thickness T8 of the second front bonding pad 311 may be less than the sixth thickness T6 of the second wiring layer 305.

The ninth thickness T9 of the second front bonding plug 313 may be greater than the seventh thickness T7 of the second via plug 309. The second shield structure 330 may be arranged beside the second front bonding pad 311.

The second shield structure 330 may be separate from the second front bonding pad 311 in the first horizontal direction D1. The second shield structure 330 may be between two second front bonding pads 311 adjacent to each other in the first horizontal direction D1. The second shield structure 330 may extend in the vertical direction D3 toward the second front surface 301f of the second substrate 301. The second shield structure 330 may be separate from the second front bonding pad 311, the second front bonding plug 313, the second wiring layer 305, and the second via plug 309. The second shield structure 330 may include a third portion, which is separate from the second front bonding pad 311 in the first horizontal direction D1, and a fourth portion, which is separate from the second front bonding plug 313 in the first horizontal direction D1.

The third portion of the second shield structure 330 may be arranged at the same vertical level as the second front bonding pad 311. The fourth portion of the second shield structure 330 may be arranged at the same vertical level as the second front bonding plug 313. The third portion and the fourth portion of the second shield structure 330 may be formed integrally. The second shield structure 330 may vertically overlap the pixel isolation layer 217.

In a plan view, the second shield structure 330 may overlap the pixel isolation layer 217. A top surface 330a of the second shield structure 330 may be coplanar with a top surface 311a of the second front bonding pad 311.

The vertical level of a bottom surface 330b of the second shield structure 330 may be lower than the vertical level of a bottom surface 311b of the second front bonding pad 311. The vertical level of the bottom surface 330b of the second shield structure 330 may be higher than the vertical level of a bottom surface 313b of the second front bonding plug 313. The second shield structure 330 may have a tenth thickness T10.

The tenth thickness T10 may correspond to the length of the second shield structure 330 in the vertical direction D3. The tenth thickness T10 of the second shield structure 330 may be greater than the eighth thickness T8 of the second front bonding pad 311. The tenth thickness T10 of the second shield structure 330 may be less than the sum of the eighth thickness T8 of the second front bonding pad 311 and the ninth thickness T9 of the second front bonding plug 313. For example, the width of the second shield structure 330 in the first horizontal direction D1 may be substantially the same as the width of the first shield structure 230 in the first horizontal direction D1.

In the cross-sectional view of FIG. 4, the width of the second shield structure 330 in the first horizontal direction D1 may be less than the width of the second front bonding pad 311 in the first horizontal direction D1.

The width of the second shield structure 330 in the first horizontal direction D1 may be less than or substantially equal to the width of the second front bonding plug 313 in the first horizontal direction D1. The second shield structure 330 may be in contact with the first shield structure 230.

In detail, at least a portion of the top surface 330a of the second shield structure 330 may be in contact with at least a portion of the bottom surface 230b of the first shield structure 230. The second shield structure 330 may be connected to the first shield structure 230. The second wiring layer 305, the second via plug 309, the second front bonding pad 311, the second front bonding plug 313, and the second shield structure 330 may include the same material.

The second wiring layer 305, the second via plug 309, the second front bonding pad 311, the second front bonding plug 313, and the second shield structure 330 may include conductive metal. For example, the second wiring layer 305, the second via plug 309, the second front bonding pad 311, the second front bonding plug 313, and the second shield structure 330 may include copper. The second insulating layer 315 may be arranged on the second front surface 301f of the second substrate 301.

The second wiring layer 305, the second contact plug 307, the second via plug 309, and the second front bonding plug 313 may be arranged inside the second insulating layer 315. The second insulating layer 315 may surround a portion of the second shield structure 330. The second shield structure 330 may further extend in the vertical direction D3 upwards from a top surface 315a of the second insulating layer 315. The second front bonding pad 311 may be disposed under the top surface 315a of the second insulating layer 315. The vertical level of the top surface 315a of the second insulating layer 315 may be lower than the vertical levels of the top surface 311a of the second front bonding pad 311 and the top surface 330a of the second shield structure 330.

The second insulating layer 315 may include silicon oxide. The second passivation layer 316 may be disposed on the top surface 315a of the second insulating layer 315.

The second passivation layer 316 may surround the side surface of the second front bonding pad 311. The top surface of the second passivation layer 316 may be coplanar with the top surface 311a of the second front bonding pad 311 and the top surface 330a of the second shield structure 330. The second passivation layer 316 may include silicon oxynitride. The bottom layer 400 may include a third substrate 401, a plurality of third transistors 403, a third wiring layer 405, a third contact plug 407, a third front bonding pad 411, a third via plug 406, and a third insulating layer 415.

The back bonding through via 317 of the middle layer 300 may be bonded to the third front bonding pad 411 of the bottom layer 400.

The second insulating layer 315 and the second substrate 301 of the middle layer 300 may be bonded to the third insulating layer 415 of the bottom layer 400. The middle layer 300 and the bottom layer 400 may have an interface B-F at which a back surface B of the middle layer 300 is bonded to a front surface F of the bottom layer 400. The third substrate 401 may include a silicon substrate.

The third substrate 401 may include a third front surface 401f and a third back surface 401b opposite to the third front surface 401f. A third transistor 403 may be arranged on the third front surface 401f of the third substrate 401. Third source and drain regions of the third transistor 403 may be arranged in the third substrate 401 but are omitted from FIG. 3 for convenience. The third contact plug 407 and the third wiring layer 405 may be connected to the third transistor 403.

The third contact plug 407 may include a metal layer, e.g., a tungsten layer. The third wiring layer 405 may be connected to the third front bonding pad 411 through the third via plug 406. The third contact plug 407 and the third wiring layer 405 may be connected to the third front bonding pad 411. The third front bonding pad 411, the third wiring layer 405, and the third via plug 406 may include a conductive metal. For example, the third front bonding pad 411, the third wiring layer 405, and the third via plug 406 may include copper. In the image sensor EX1, the first front bonding pad 211 of the top layer 200 may be bonded to the second front bonding pad 311 of the middle layer 300 and the top layer 200 and the middle layer 300 may have the interface F-F at which the front surface F of the top layer 200 is bonded to the front surface F of the middle layer 300.

In the image sensor EX1, the back bonding through via 317 of the middle layer 300 may be bonded to the third front bonding pad 411 of the bottom layer 400.

The middle layer 300 and the bottom layer 400 may have the interface B-F at which the back surface B of the middle layer 300 is bonded to the front surface F of the bottom layer 400. When the vertical level of the top surface 230a of the first shield structure 230 is lower than the vertical level of the top surface 211a of the first front bonding pad 211, it may be difficult to prevent coupling from occurring between the two first front bonding plugs 213 adjacent to each other in the first horizontal direction D1.

Coupling may intensify with the miniaturization of the image sensor EX1. According to the disclosure, the image sensor EX1 may include the bottom layer 400, the middle layer 300, and the top layer 200, which are sequentially stacked on each other.

The top layer 200 may include the first front bonding pad 211 at the bottom thereof, the first front bonding plug 213 connected to the first front bonding pad 211 and extending upwards in the vertical direction D3, and the first shield structure 230 between two first front bonding pads 211 adjacent to each other in the first horizontal direction D1. The vertical level of the top surface 230a of the first shield structure 230 may be higher than the vertical level of the top surface 211a of the first front bonding pad 211. The middle layer 300 may include a second front bonding pad 311 on the top thereof, the second front bonding plug 313 connected to the second front bonding pad 311 and extending downwards in the vertical direction D3, and the second shield structure 330 between two second front bonding pads 311 adjacent to each other in the first horizontal direction D1.

The vertical level of the bottom surface 330b of the second shield structure 330 may be lower than the vertical level of the bottom surface 311b of the second front bonding pad 311. Accordingly, coupling may not occur between two first front bonding plugs 213 adjacent to each other in the first horizontal direction D1.

For these reasons, the electrical characteristics and reliability of the image sensor EX1 may be improved. In the cross-sectional view of FIG. 4, the width of the first shield structure 230 in the first horizontal direction D1 may be less than the width of the first front bonding pad 211 in the first horizontal direction D1.

The width of the first shield structure 230 in the first horizontal direction D1 may be less than or substantially equal to the width of the first front bonding plug 213 in the first horizontal direction D1. In the cross-sectional view of FIG. 4, the width of the second shield structure 330 in the first horizontal direction D1 may be less than the width of the second front bonding pad 311 in the first horizontal direction D1.

The width of the second shield structure 330 in the first horizontal direction D1 may be less than or substantially equal to the width of the second front bonding plug 313 in the first horizontal direction D1. Accordingly, space taken by the first shield structure 230 and the second shield structure 330 may be minimized. For these reasons, the integration density of the image sensor EX1 may be increased.

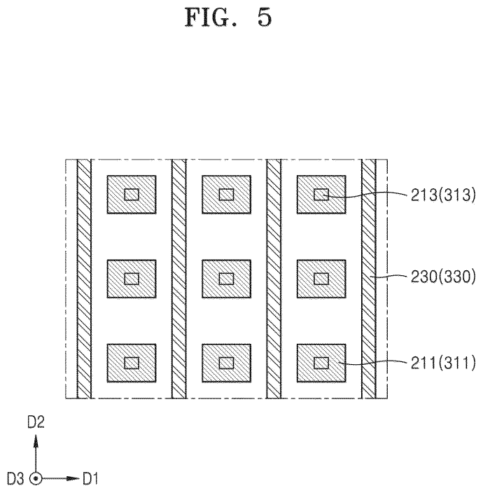

FIG. 5 is a schematic plan view illustrating the structure of an image sensor according to an embodiment. In detail, FIG. 5 is a plan view showing the planar arrangement relationship between the first front bonding pad 211 and the first shield structure 230, which have been described with reference to FIGS. 3 and 4 or the planar arrangement relationship between the second front bonding pad 311 and the second shield structure 330, which have been described with reference to FIGS. 3 and 4. Redundant descriptions given above with reference to FIGS. 3 and 4 are omitted from the descriptions of FIG. 5 below. Referring to FIG. 5, the first front bonding pad 211 and the second front bonding pad 311 may have a rectangular planar shape.

However, this is just an example. The first front bonding pad 211 and the second front bonding pad 311 may have various planar shapes, such as a circle, an ellipse, a polygon, and a ring. There may be a plurality of first front bonding pads 211.

There may be a plurality of second front bonding pads 311. The first front bonding pads 211 may be two-dimensionally arranged in the first horizontal direction D1 and the second horizontal direction D2. The second front bonding pads 311 may be two-dimensionally arranged in the first horizontal direction D1 and the second horizontal direction D2. One of the first front bonding pads 211 may overlap one of the second front bonding pads 311 in the vertical direction D3.

The first front bonding pad 211 may overlap the first front bonding plug 213 in the vertical direction D3. The second front bonding pad 311 may overlap the second front bonding plug 313 in the vertical direction D3. The first shield structure 230 may be between two first front bonding pads 211 adjacent to each other in the first horizontal direction D1.

There may be a plurality of first shield structures 230. The first shield structures 230 may extend in the second horizontal direction D2. The second shield structure 330 may be between two second front bonding pads 311 adjacent to each other in the first horizontal direction D1. There may be a plurality of second shield structures 330. The second shield structures 330 may extend in the second horizontal direction D2. One of the first shield structures 230 may overlap the one of the second shield structures 330 in the vertical direction D3.

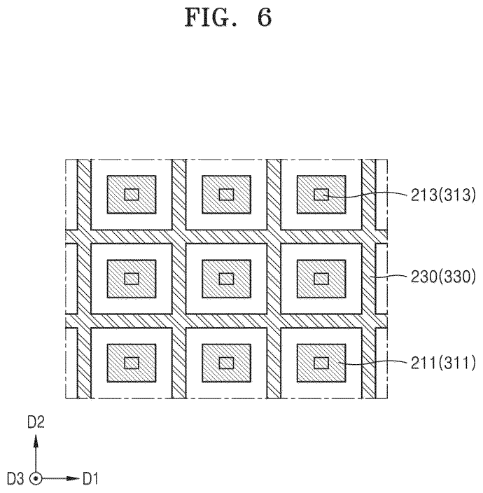

FIG. 6 is a schematic plan view illustrating the structure of an image sensor according to an embodiment.

In detail, FIG. 6 is a plan view showing the planar arrangement relationship between the first front bonding pad 211 and the first shield structure 230, which have been described with reference to FIGS. 3 and 4 or the planar arrangement relationship between the second front bonding pad 311 and the second shield structure 330, which have been described with reference to FIGS. 3 and 4. Redundant descriptions given above with reference to FIGS. 3 and 4 are omitted from the descriptions of FIG. 6 below. Referring to FIG. 6, the first front bonding pad 211 and the second front bonding pad 311 may have a rectangular planar shape.

However, this is just an example. The first front bonding pad 211 and the second front bonding pad 311 may have various planar shapes, such as a circle, an ellipse, a polygon, and a ring. There may be a plurality of first front bonding pads 211.

There may be a plurality of second front bonding pads 311. The first front bonding pads 211 may be two-dimensionally arranged in the first horizontal direction D1 and the second horizontal direction D2. The second front bonding pads 311 may be two-dimensionally arranged in the first horizontal direction D1 and the second horizontal direction D2. One of the first front bonding pads 211 may overlap one of the second front bonding pads 311 in the vertical direction D3.

The first front bonding pad 211 may overlap the first front bonding plug 213 in the vertical direction D3. The second front bonding pad 311 may overlap the second front bonding plug 313 in the vertical direction D3. In a plan view, the first shield structure 230 may surround the first front bonding pad 211.

In a plan view, the first shield structure 230 may surround the first front bonding plug 213. In a plan view, the first shield structure 230 may have a mesh shape. The first shield structure 230 may extend in the first horizontal direction D1 and the second horizontal direction D2. In a plan view, the second shield structure 330 may surround the second front bonding pad 311.

In a plan view, the second shield structure 330 may surround the second front bonding plug 313. In a plan view, the second shield structure 330 may have a mesh shape. The second shield structure 330 may extend in the first horizontal direction D1 and the second horizontal direction D2.

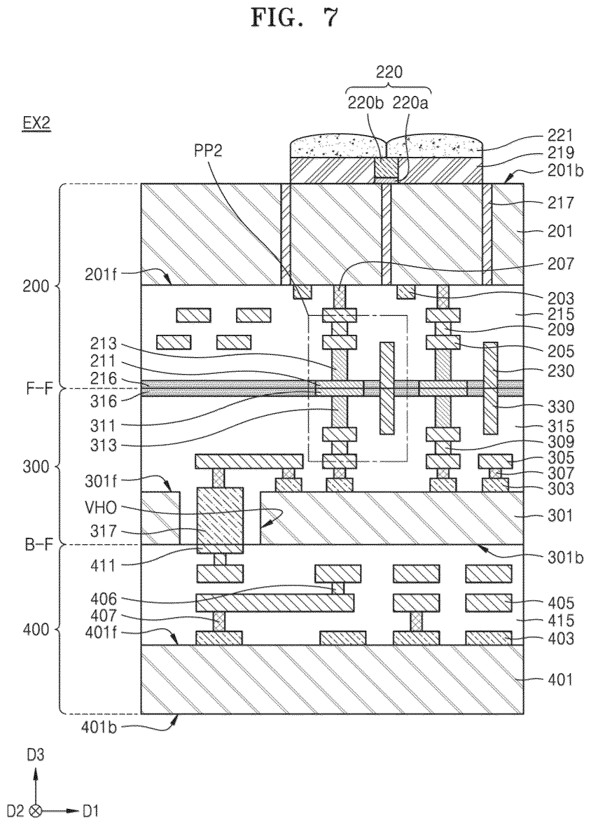

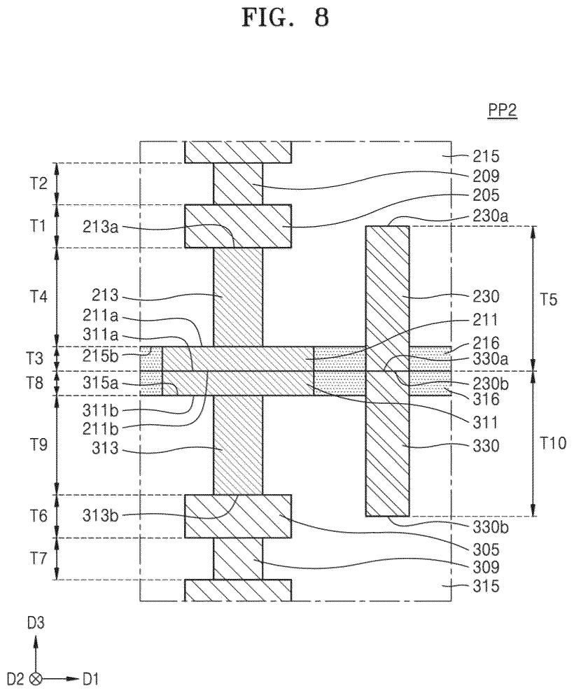

FIG. 7 is a schematic cross-sectional view illustrating the structure of an image sensor according to an embodiment. FIG. 8 is an enlarged view of a region PP2 in FIG. 7. Redundant descriptions given above with reference to FIGS. 3 and 4 are omitted from the descriptions of FIGS. 7 and 8 below. Referring to FIGS. 7 and 8, an image sensor EX2 may include the bottom layer 400, the middle layer 300, and the top layer 200, which are sequentially stacked on each other.

The top layer 200 may include the first substrate 201, the pixel isolation layer 217, the color filter 219, the lens 221, the plurality of first transistors 203, the first wiring layer 205, the first contact plug 207, the first via plug 209, the first front bonding pad 211, the first front bonding plug 213, the first shield structure 230, the first insulating layer 215, and the first passivation layer 216.

The vertical level of the top surface 230a of the first shield structure 230 may be higher than the vertical level of the top surface 213a of the first front bonding plug 213.

The first front bonding pad 211 may have the third thickness T3.

The first front bonding plug 213 may have the fourth thickness T4. The first shield structure 230 may have the fifth thickness T5. The fifth thickness T5 of the first shield structure 230 may be greater than the sum of the third thickness T3 of the first front bonding pad 211 and the fourth thickness T4 of the first front bonding plug 213. The fifth thickness T5 of the first shield structure 230 may be different from the fourth thickness T4 of the first front bonding plug 213. The fifth thickness T5 of the first shield structure 230 may be greater than the fourth thickness T4 of the first front bonding plug 213. The middle layer 300 may include the second substrate 301, the plurality of second transistors 303, the back bonding through via 317, the second wiring layer 305, the second contact plug 307, the second via plug 309, the second front bonding pad 311, the second front bonding plug 313, the second shield structure 330, the second insulating layer 315, and the second passivation layer 316.

The vertical level of the bottom surface 330b of the second shield structure 330 may be lower than the vertical level of the bottom surface 313b of the second front bonding plug 313.

The second front bonding pad 311 may have the eighth thickness T8.

The second front bonding plug 313 may have the ninth thickness T9. The second shield structure 330 may have the tenth thickness T10. The tenth thickness T10 of the second shield structure 330 may be greater than the sum of the eighth thickness T8 of the second front bonding pad 311 and the ninth thickness T9 of the second front bonding plug 313.

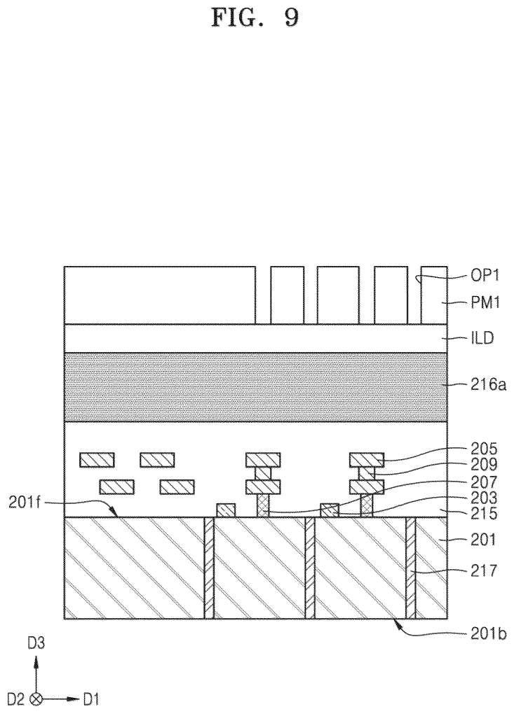

FIGS. 9 to 15 are cross-sectional views illustrating a method of manufacturing the image sensor EX1 of FIG. 3, according to an embodiment. Redundant descriptions given above with reference to FIGS. 3 and 4 are brief or omitted from the descriptions of FIGS. 9 to 15 below.

Referring to FIG. 9, the first substrate 201 may be provided. The first substrate 201 may include the first front surface 201f and the first back surface 201b opposite to the first front surface 201f. A pixel isolation layer 217 may be formed in the first substrate 201. A plurality of first transistors 203 may be formed on the first front surface 201f of the first substrate 201. A first contact plug 207, a first wiring layer 205, and a first via plug 209 may be formed to be connected to each of the first transistors 203. The first insulating layer 215 may be formed on the first front surface 201f of the first substrate 201 to cover the first contact plug 207, the first wiring layer 205, and the first via plug 209. A first passivation film 216a may be formed on the first insulating layer 215.

A protective insulating layer ILD may be formed on the first passivation film 216a. The first passivation film 216a may include silicon oxynitride. The protective insulating layer ILD may include silicon oxide. A first mask pattern PM1 may be formed on the protective insulating layer ILD.

The first mask pattern PM1 may include a first opening OP1 that exposes at least a portion of the top surface of the protective insulating layer ILD. There may be a plurality of first openings OP1.

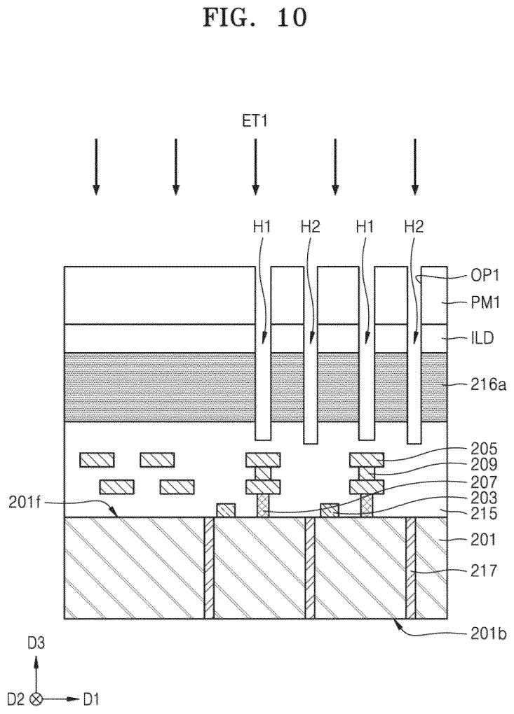

Referring to FIG. 10, a first etching process ET1 may be performed on the protective insulating layer ILD, the first passivation film 216a, and the first insulating layer 215 by using the first mask pattern PM1 as an etch mask. The first etching process ET1 may use dry etching. Due to the first etching process ET1, a first hole H1 and a second hole H2 may be formed, penetrating the protective insulating layer ILD and the first passivation film 216a.

The first hole H1 and the second hole H2 may each further penetrate a portion of the first insulating layer 215. However, the first hole H1 and the second hole H2 may not expose the first wiring layer 205. Each of the first hole H1 and the second hole H2 may overlap at least one of the first openings OP1 in the vertical direction D3. There may be a plurality of first holes H1 and second holes H2.

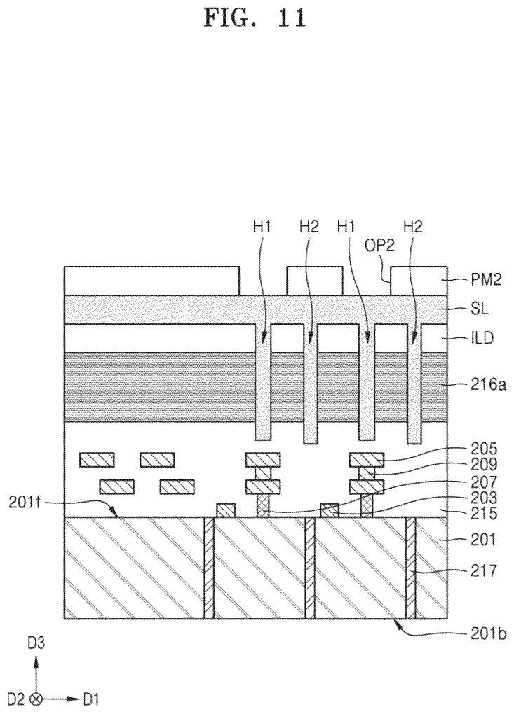

Referring to FIG. 11, the first mask pattern PM1 in FIG. 10 may be removed. Subsequently, a sacrificial film SL filling the first hole H1 and the second hole H2 may be formed. The sacrificial film SL may cover the top surface of the protective insulating layer ILD. The sacrificial film SL may include a polymeric material. A second mask pattern PM2 may be formed on the sacrificial film SL.

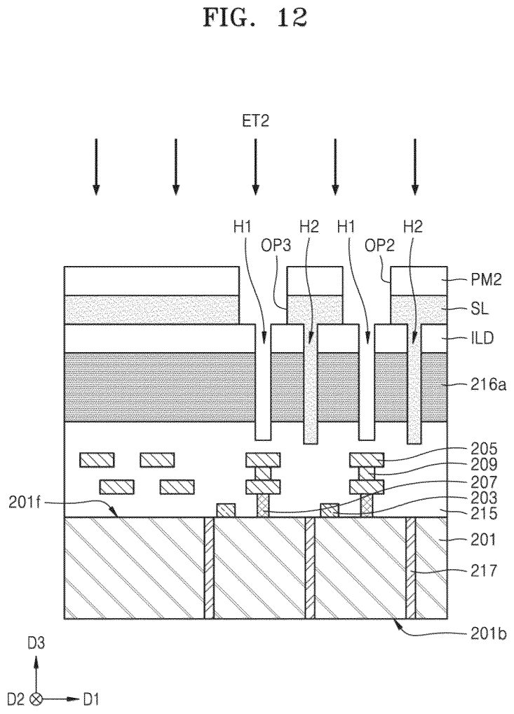

The second mask pattern PM2 may include a second opening OP2 that exposes at least a portion of the top surface of the sacrificial film SL. The second opening OP2 may overlap the first hole H1 in the vertical direction D3. The width of the second opening OP2 in the first horizontal direction D1 may be greater than the width of the first hole H1 in the first horizontal direction D1. The second opening OP2 may not overlap the second hole H2 in the vertical direction D3. Referring to FIG. 12, a second etching process ET2 may be performed on the sacrificial film SL by using the second mask pattern PM2 as an etch mask.

The second etching process ET2 may use dry etching. Due to the second etching process ET2, a portion of the sacrificial film SL may be removed.

The removed portion of the sacrificial film SL may correspond to a portion of the sacrificial film SL that overlaps the second opening OP2 in the vertical direction D3. Due to the second etching process ET2, a portion of the sacrificial film SL that fills the first hole H1 may be removed. Due to the second etching process ET2, a portion of the sacrificial film SL on the protective insulating layer ILD may be removed. When the portion of the sacrificial film SL is removed by the second etching process ET2, a third opening OP3 may be formed in the sacrificial film SL.

The width of the third opening OP3 in the first horizontal direction D1 may be substantially the same as the width of the second opening OP2 in the first horizontal direction D1. The width of the third opening OP3 in the first horizontal direction D1 may be greater than the width of the first hole H1 in the first horizontal direction D1. Due to the second etching process ET2, the thickness of the second mask pattern PM2 may be reduced. However, the second mask pattern PM2 may not be completely removed but may partially remain.

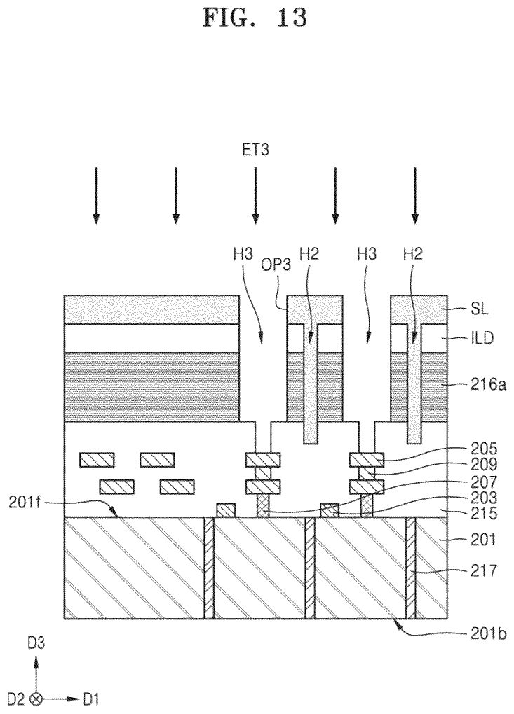

Referring to FIG. 13, a third etching process ET3 may be performed on the protective insulating layer ILD, the first passivation film 216a, and the first insulating layer 215 by using the second mask pattern PM2 in FIG. 12 as an etch mask.

The third etching process ET3 may use dry etching. Each of the protective insulating layer ILD, the first passivation film 216a, and the first insulating layer 215 may be partially removed by the third etching process ET3, thereby forming a third hole H3.

At a vertical level at which the protective insulating layer ILD overlaps the first passivation film 216a in the first horizontal direction D1, the width of the third hole H3 in the first horizontal direction D1 may be substantially the same as the width of the third opening OP3 in the first horizontal direction D1. As a portion of the first insulating layer 215 is further etched by the third etching process ET3, at least a portion of the first wiring layer 205 may be exposed.

Subsequently, the second mask pattern PM2 may be removed.

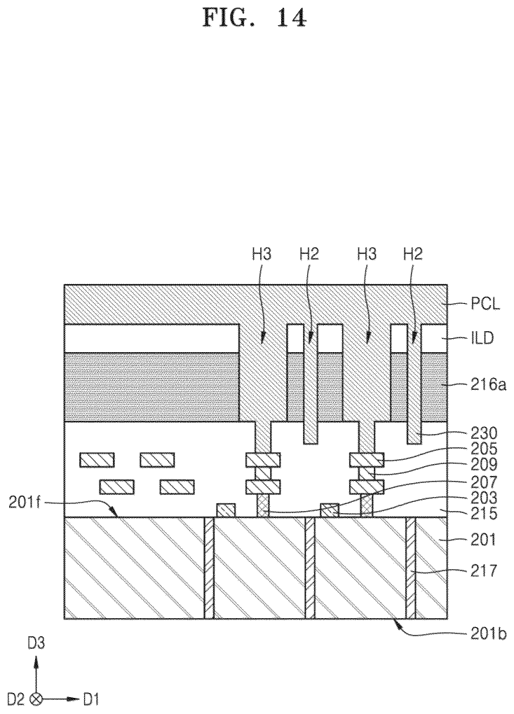

Referring to FIG. 14, a conductive film PCL may be formed to fill the second hole H2 and the third hole H3.

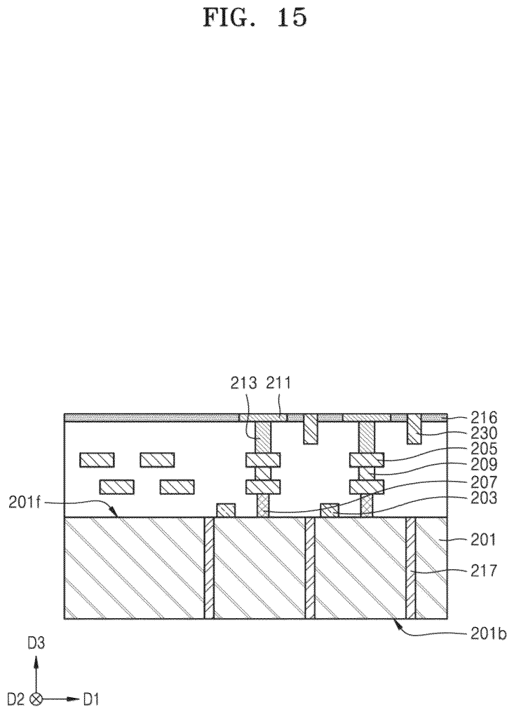

The conductive film PCL may also be formed on the top surface of the protective insulating layer ILD. The conductive film PCL may contact the first wiring layer 205 through the third hole H3. Referring to FIG. 15, a planarization process may be performed on the conductive film PCL, the protective insulating layer ILD, and the first passivation film 216a in FIG. 14.

For example, the planarization process may include chemical mechanical polishing (CMP). Due to the planarization process, the first front bonding pad 211, the first front bonding plug 213, and the first shield structure 230 may be formed from the conductive film PCL in FIG. 14. The protective insulating layer ILD may be completely removed by the planarization process. Due to the planarization process, the first passivation layer 216 may be formed from the first passivation film 216a. Referring back to FIG. 3, the first substrate 201 in FIG. 15 may be turned upside down. The color filter 219 and the lens 221 may be formed on the first back surface 201b of the first substrate 201.

Accordingly, the top layer 200 may be formed. The middle layer 300 may be prepared separately from the top layer 200.

The middle layer 300 may include the second substrate 301, the plurality of second transistors 303, the back bonding through via 317, the second wiring layer 305, the second contact plug 307, the second via plug 309, the second front bonding pad 311, the second front bonding plug 313, the second shield structure 330, the second insulating layer 315, and the second passivation layer 316. The second substrate 301 may include the second front surface 301f and the second back surface 301b opposite to the second front surface 301f.

A through via hole VHO may be formed inside the second substrate 301 to penetrate the second substrate 301 from the second front surface 301f to the second back surface 301b of the second substrate 301. The back bonding through via 317, which is insulated from the second substrate 301 by the second insulating layer 315, may be formed in the through via hole VHO. The second transistors 303 may be formed on the second front surface 301f of the second substrate 301.

The second contact plug 307, the second wiring layer 305, and the second via plug 309 may be formed to be connected to each of the second transistors 303. The second insulating layer 315 may be formed on the second front surface 301f of the second substrate 301 to cover the second contact plug 307, the second wiring layer 305, and the second via plug 309. The second front bonding pad 311, the second front bonding plug 313, the second shield structure 330, and the second passivation layer 316 of the middle layer 300 may be formed by a method that is similar to the method of forming the first front bonding pad 211, the first front bonding plug 213, the first shield structure 230, and the first passivation layer 216, which is described above with reference to FIGS. 9 to 15.

Subsequently, the first front bonding pad 211 of the top layer 200 may be bonded to the second front bonding pad 311 of the middle layer 300.

When the first front bonding pad 211 and the second front bonding pad 311 include copper, a copper pad may be bonded to a copper pad. The bottom layer 400 may be prepared separated from the top layer 200 and the middle layer 300.

The bottom layer 400 may include the third substrate 401, the plurality of third transistors 403, the third wiring layer 405, the third contact plug 407, the third front bonding pad 411, the third via plug 406, and the third insulating layer 415. The back bonding through via 317 of the middle layer 300 may be bonded to the third front bonding pad 411 of the bottom layer 400.

The second insulating layer 315 and the second substrate 301 of the middle layer 300 may be bonded to the third insulating layer 415 of the bottom layer 400. When the back bonding through via 317 and the third front bonding pad 411 include copper, a copper via may be bonded to a copper pad. As a result, the image sensor EX1 of FIG. 3 may be manufactured.

While the disclosure has been particularly shown and described with reference to embodiments thereof, it will be understood that various changes in form and details may be made therein without departing from the spirit and scope of the following claims.

What is claimed is:

1. An image sensor comprising:
a top layer comprising a first substrate, the first substrate comprising:
a first front surface and a first back surface opposite to the first front surface;
a first front bonding pad on the first front surface;
a first front bonding plug connected to the first front bonding pad and extending in a vertical direction toward the first front surface; and
a first shield structure separate from the first front bonding pad in a first horizontal direction;
a middle layer below the top layer and bonded to the top layer, the middle layer comprising:
a second substrate comprising a second front surface and a second back surface opposite to the second front surface;
a second front bonding pad on the second front surface;
a second front bonding plug connected to the second front bonding pad and extending in the vertical direction toward the second front surface; and
a second shield structure separated from the second front bonding pad in the first horizontal direction; and
a bottom layer below the middle layer and bonded to the middle layer, the bottom layer comprising a third substrate and a transistor on the third substrate,
wherein a vertical level of a top surface of the first shield structure is higher than a vertical level of a top surface of the first front bonding pad.

2. The image sensor of claim 1, wherein a vertical level of a bottom surface of the second shield structure is lower than a vertical level of a bottom surface of the second front bonding pad.

3. The image sensor of claim 1, wherein a width of the first shield structure in the first horizontal direction is less than a width of the first front bonding pad in the first horizontal direction.

4. The image sensor of claim 1, wherein a width of the first shield structure in the first horizontal direction is less than a width of the first front bonding plug in the first horizontal direction.

5. The image sensor of claim 1, wherein the top layer further comprises:
a first wiring layer and a second wiring layer, wherein the first and the second wiring layers are between the first substrate and the first front bonding plug, the first and the second wiring layers are at different vertical levels, and the first wiring layer is connected to the first front bonding plug; and
a first via plug connecting the first wiring layer to the second wiring layer, and
wherein a length of the first front bonding plug in the vertical direction is greater than a length of the first via plug in the vertical direction.

6. The image sensor of claim 1, wherein a length of the first shield structure in the vertical direction is greater than a sum of a length of the first front bonding pad in the vertical direction and a length of the first front bonding plug in the vertical direction.

7. The image sensor of claim 1, wherein the vertical level of the top surface of the first shield structure is higher than a vertical level of a top surface of the first front bonding plug.

8. The image sensor of claim 1, wherein the top layer further comprises a first wiring layer between the first substrate and the first front bonding plug,
wherein the first wiring layer is connected to the first front bonding plug, and
wherein a length of the first front bonding pad in the vertical direction is less than a length of the first wiring layer in the vertical direction.

9. The image sensor of claim 1, wherein the top layer further comprises a floating diffusion node inside the first substrate, and
wherein the first front bonding pad, the first front bonding plug, the second front bonding pad, and the second front bonding plug are connected to the floating diffusion node.

10. The image sensor of claim 1, wherein the top layer further comprises:
a first insulating layer surrounding the first front bonding plug and covering the top surface of the first front bonding pad and a first portion of a side surface of the first shield structure; and
a first passivation layer below the first insulating layer, and
wherein the first passivation layer surrounds a side surface of the first front bonding pad and a second portion of the side surface of the first shield structure.

11. The image sensor of claim 10, wherein the first shield structure protrudes upwards from a bottom surface of the first insulating layer toward the first substrate, and
wherein a bottom surface of the first shield structure is coplanar with a bottom surface of the first passivation layer.

12. The image sensor of claim 10, wherein the middle layer further comprises:
a second insulating layer surrounding the second front bonding plug and covering a bottom surface of the second front bonding pad and a first portion of a side surface of the second shield structure; and
a second passivation layer on the second insulating layer,
wherein the second passivation layer surrounds a side surface of the second front bonding pad and a second portion of the side surface of the second shield structure, and
wherein the first shield structure is in contact with the second shield structure.

13. An image sensor comprising:
a top layer comprising a first substrate, the first substrate comprising:
a first front surface and a first back surface opposite to the first front surface;
a first front bonding pad on the first front surface;
a first front bonding plug connected to the first front bonding pad and extending in a vertical direction toward the first front surface; and
a first shield structure comprising a first portion separate from the first front bonding pad in a first horizontal direction and a second portion separate from the first front bonding plug in the first horizontal direction;
a middle layer below the top layer and bonded to the top layer, the middle layer comprising:
a second substrate comprising a second front surface and a second back surface opposite to the second front surface;
a second front bonding pad on the second front surface;
a second front bonding plug connected to the second front bonding pad and extending in the vertical direction toward the second front surface; and
a second shield structure comprising a third portion separate from the second front bonding pad in the first horizontal direction and a fourth portion separate from the second front bonding plug in the first horizontal direction; and
a bottom layer below the middle layer and bonded to the middle layer, the bottom layer comprising a third substrate and a transistor on the third substrate,
wherein the first shield structure and the second shield structure extend in a second horizontal direction that intersects with the first horizontal direction.

14. The image sensor of claim 13, wherein, from a plan view perspective, the first shield structure surrounds the first front bonding pad and the first front bonding plug.

15. The image sensor of claim 13, wherein, from a plan view perspective, the first shield structure has a mesh shape.

16. The image sensor of claim 13, wherein the first front bonding pad and the first front bonding plug are formed integrally.

17. The image sensor of claim 13, wherein a length of the first shield structure in the vertical direction is greater than a length of the first front bonding plug in the vertical direction.

18. An image sensor comprising:
a top layer comprising a first substrate, the first substrate comprising:
a first front surface and a first back surface opposite to the first front surface;
a color filter and a lens sequentially stacked on the first back surface;
a pixel isolation layer penetrating the first substrate;
a first transistor on the first front surface of the first substrate;
a first contact plug connected to the first transistor;
a first wiring layer below the first contact plug and connected to the first contact plug;
a first front bonding plug below the first wiring layer and connected to the first wiring layer;
a first front bonding pad below the first front bonding plug and in contact with the first front bonding plug; and
a first shield structure separate from the first front bonding pad in a first horizontal direction;
a middle layer below the top layer and bonded to the top layer, the middle layer comprising a second substrate, the second substrate comprising:
a second front surface and a second back surface opposite to the second front surface;
a second transistor on the second front surface;
a second contact plug connected to the second transistor;
a second wiring layer above the second contact plug and connected to the second contact plug;
a second front bonding plug above the second wiring layer and connected to the second wiring layer;
a second front bonding pad above the second front bonding plug and in contact with the second front bonding plug; and
a second shield structure separate from the second front bonding pad in the first horizontal direction; and
a bottom layer below the middle layer and bonded to the middle layer, the bottom layer comprising a third substrate and a transistor on the third substrate,
wherein a vertical level of a top surface of the first shield structure is higher than a vertical level of a top surface of the first front bonding pad.

19. The image sensor of claim 18, wherein a vertical level of a bottom surface of the second shield structure is lower than a vertical level of a bottom surface of the second front bonding pad.

20. The image sensor of claim 18, wherein a width of the first shield structure in the first horizontal direction is less than a width of the first front bonding pad in the first horizontal direction.
